(19) United States
(12) Patent Application Publication
(10) Pub. No.: US 2026/0066874 A1
(43) Pub. Date: Mar. 5, 2026

(54) RADIO FREQUENCY FILTER INCLUDING HIGH ASPECT RATIO BULK ACOUSTIC WAVE RESONATORS

(71) Applicant: SKYWORKS SOLUTIONS, INC., Irvine, CA (US)

(72) Inventors: Yiliu Wang, Irvine, CA (US); Zhengliu Zhou, Irvine, CA (US); Nan Wu, Irvine, CA (US); Jinjing Li, Irvine, CA (US)

(21) Appl. No.: 19/316,335

(22) Filed: Sep. 2, 2025

Related U.S. Application Data
(60) Provisional application No. 63/690,407, filed on Sep. 4, 2024.

(51) Int. Cl. H03H 9/56; H03H 9/13; H03H 9/17

(52) U.S. Cl. CPC H03H 9/568; H03H 9/132; H03H 9/173; H03H 9/175; H03H 9/564

(57) ABSTRACT

Aspects and embodiments disclosed herein include a radio frequency filter comprising a plurality of series arm bulk acoustic wave resonators connected in series between an input and an output of the filter, and a plurality of shunt bulk acoustic wave resonators connected between nodes between adjacent series arm bulk acoustic wave resonators and ground. At least one of the plurality of series arm bulk acoustic wave resonators has a greater aspect ratio than at least one of the plurality of shunt bulk acoustic wave resonators.

### CROSS-REFERENCE TO RELATED APPLICATIONS

This application claims priority under 35 U.S.C. § 119(e) to U.S. Provisional Patent Application Ser. No. 63/690,407, titled “RADIO FREQUENCY FILTER INCLUDING HIGH ASPECT RATIO BULK ACOUSTIC WAVE RESONATORS,” filed Sep. 4, 2024, the entire content of which is incorporated herein by reference for all purposes.

### TECHNICAL FIELD

Embodiments of this disclosure relate to radio frequency filters including multiple bulk acoustic wave resonators.

### Description of Related Technology

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic wave resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer. A plurality of acoustic wave filters can be arranged as a multiplexer.

### SUMMARY

In accordance with one aspect, there is provided a radio frequency filter. The radio frequency filter comprises a plurality of series arm bulk acoustic wave resonators connected in series between an input and an output of the filter, and a plurality of shunt bulk acoustic wave resonators connected between nodes between adjacent series arm bulk acoustic wave resonators and ground. At least one of the plurality of series arm bulk acoustic wave resonators has a greater aspect ratio than at least one of the plurality of shunt bulk acoustic wave resonators.

In some embodiments, the at least one of the plurality of series arm bulk acoustic wave resonators has a greater aspect ratio than any of the plurality of shunt bulk acoustic wave resonators.

In some embodiments, each of the plurality of series arm bulk acoustic wave resonators have greater aspect ratios than each of the plurality of shunt bulk acoustic wave resonators.

In some embodiments, one of the input or the output is an antenna port and the at least one of the plurality of series arm bulk acoustic wave resonators is a series arm bulk acoustic wave resonator closest to the antenna port.

In some embodiments, the aspect ratio of the at least one of the plurality of series arm bulk acoustic wave resonators is at least 2:1.

In some embodiments, the aspect ratio of the at least one of the plurality of series arm bulk acoustic wave resonators is at least 3:1.

In some embodiments, the aspect ratio of the at least one of the plurality of series arm bulk acoustic wave resonators is 5:1 or more.

In some embodiments, the at least one of the plurality of series arm bulk acoustic wave resonators includes a first side and a second side, the first side being longer than the second side, an electrical connection to a first electrode of the at least one of the plurality of series arm bulk acoustic wave resonators being disposed on the first side.

In some embodiments, the at least one of the plurality of series arm bulk acoustic wave resonators includes a third side, the first side and the third side each being longer than all other sides of the at least one of the plurality of series arm bulk acoustic wave resonators, an electrical connection to a second electrode of the at least one of the plurality of series arm bulk acoustic wave resonators being disposed on the third side.

In some embodiments, the plurality of series arm bulk acoustic wave resonators are film bulk acoustic wave resonators.

In some embodiments, the plurality of series arm bulk acoustic wave resonators are solidly mounted resonators.

In accordance with another aspect, there is provided an electronic device module comprising a radio frequency filter including a plurality of series arm bulk acoustic wave resonators connected in series between an input and an output of the filter, and a plurality of shunt bulk acoustic wave resonators connected between nodes between adjacent series arm bulk acoustic wave resonators and ground. At least one of the plurality of series arm bulk acoustic wave resonators has a greater aspect ratio than at least one of the plurality of shunt bulk acoustic wave resonators.

The electronic device module may be included in a radio frequency device.

In accordance with another aspect, there is provided a multiplexer including a plurality of radio frequency filters. At least one of the plurality of radio frequency filters comprises a plurality of series arm bulk acoustic wave resonators connected in series between an input and an output of the filter, and a plurality of shunt bulk acoustic wave resonators connected between nodes between adjacent series arm bulk acoustic wave resonators and ground. At least one of the plurality of series arm bulk acoustic wave resonators has a greater aspect ratio than at least one of the plurality of shunt bulk acoustic wave resonators.

In some embodiments, the at least one of the plurality of radio frequency filters has a higher operating frequency than at least one other of the plurality of radio frequency filters.

In some embodiments, the at least one of the plurality of radio frequency filters has a higher operating frequency than each other of the plurality of radio frequency filters.

In some embodiments, the at least one of the plurality of series arm bulk acoustic wave resonators has a greater aspect ratio than any of the plurality of shunt bulk acoustic wave resonators.

In some embodiments, each of the plurality of series arm bulk acoustic wave resonators have greater aspect ratios than any of the plurality of shunt bulk acoustic wave resonators.

In some embodiments, one of the input or the output is an antenna port and the at least one of the plurality of series arm bulk acoustic wave resonators is a series arm bulk acoustic wave resonator closest to the antenna port.

The multiplexer may be included in an electronic device.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of a solidly mounted resonator;

FIG. 3 is a schematic diagram of a radio frequency ladder filter;

FIG. 4 illustrates how the aspect ratio of a bulk acoustic wave resonator is defined herein;

FIG. 5 illustrates the locations of electrical connections to electrodes of bulk acoustic wave resonators as disclosed herein;

FIG. 6 illustrates examples of shapes of bulk acoustic wave resonators with different aspect ratios;

FIG. 7 illustrates results of a simulation of the effect on quality factor of a bulk acoustic wave resonator of increasing the resonator aspect ratio from 1.0 to 3.7;

FIG. 8 is a chart comparing results of a simulation of insertion loss of bulk acoustic wave resonators having different aspect ratios;

FIG. 9 is a chart comparing results of a simulation of out of band filter return loss for a ladder filters including series arm resonators having different aspect ratios;

FIG. 10 illustrates the results of simulations of maximum power handling in ladder filters including series arm bulk acoustic wave resonators having different aspect ratios;

FIG. 11 illustrates an embodiment of an electronics module;

FIG. 12 illustrates an example of a front-end module which may be used in an electronic device; and

FIG. 13 illustrates an example of an electronic device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally include a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined in part by the thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

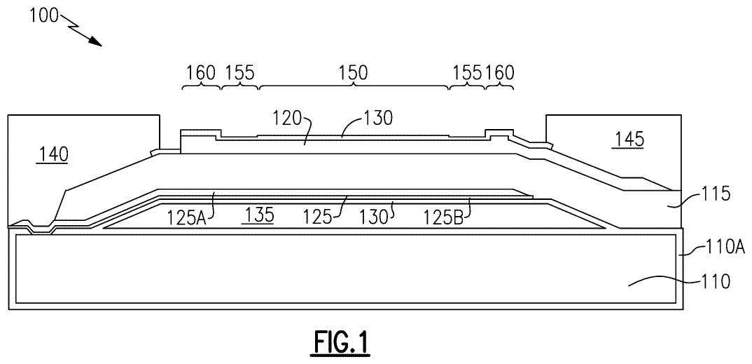

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AlN) or scandium-doped aluminum nitride (AlₓSc₁₋ₓN, referred to herein without subscripts as AlScN). A top electrode 120 (often abbreviated MTE for Metal Top Electrode) is disposed on top of a portion of the layer or film of piezoelectric material 115 and a bottom electrode 125 (often abbreviated MBE for Metal Bottom Electrode) is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 including a main active domain in the layer or film of piezoelectric material 115 in which a main acoustic wave is excited during operation. The central region may have a width of, for example, between about 20μm and about 100μm. A recessed frame region or regions 155 may bound and define the lateral extent of the central region 150. The recessed frame regions may have a width of, for example, about 1μm. The recessed frame region(s) 155 may be defined by areas that have a thinner dielectric material layer 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material layers in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric material layer 130 in the recessed frame region(s) 155 is typically etched during manufacturing to achieve a desired difference in acoustic velocity between the central region 150 and the recessed frame region(s) 155. Accordingly, the dielectric material layer 130 initially deposited in both the central region 150 and recessed frame region(s) 155 is deposited with a sufficient thickness that allows for etching of sufficient dielectric material in the recessed frame region(s) 155 to achieve a desired difference in thickness of the dielectric material layer 130 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode 120 in the central region 150 may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner dielectric material layer 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

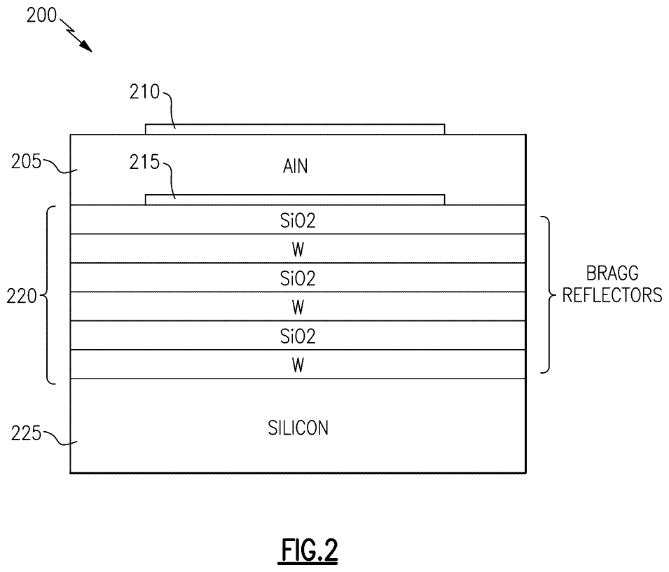

Another form of BAW resonator is a solidly mounted resonator (SMR). An example of an SMR is illustrated generally at 200 in FIG. 2. As illustrated, the SMR 200 includes a piezoelectric material layer 205, a top electrode 210 on the piezoelectric material layer 205, and a bottom electrode 215 on a lower surface of the piezoelectric material layer 205. The piezoelectric material layer 205 can be an aluminum nitride layer. In other instances, the piezoelectric material layer 205 can be formed of any other suitable piezoelectric material. The bottom electrode 215 can be grounded in certain instances. In some other instances, the bottom electrode 215 can be floating. Bragg reflectors 220 are disposed between the bottom electrode 215 and a semiconductor substrate 225. The semiconductor substrate 225 can be a silicon substrate. Any suitable Bragg reflectors can be implemented. For example, the Bragg reflectors can be SiO₂/W.

It should be appreciated that the BAW resonators and piezoelectric material layers illustrated in the figures are illustrated in a highly simplified form. The relative dimensions of the different features are not shown to scale. Further, typical BAW resonators may include additional features or layers not illustrated.

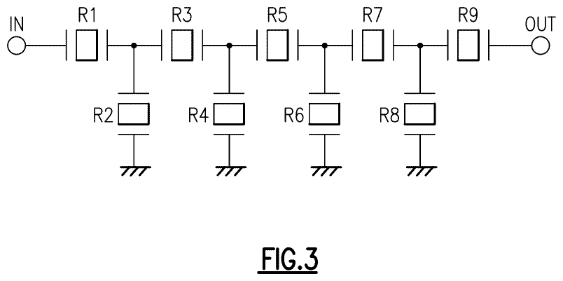

In some embodiments, multiple BAW resonators as disclosed herein, such as film bulk acoustic wave resonators, solidly mounted resonators, or a combination of both may be combined into a filter, for example, an RF ladder filter such as that schematically illustrated in FIG. 3. The RF ladder filter includes a plurality of series arm resonators (or simply “series” resonators) R1, R3, R5, R7, and R9, and a plurality of parallel (or shunt) resonators R2, R4, R6, and R8. As shown, the plurality of series resonators R1, R3, R5, R7, and R9 are connected in series between the input (IN) and the output (OUT) of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

As the market for radio frequency communication devices, for example, cell phones, continues to migrate to operation in the 5G NR frequency bands, as well as increasing utilization of carrier aggregation technologies there is an increasing demand for radio frequency filters utilized in these devices to exhibit improved performance factors. These performance factors include, for example, lower insertion loss, improved power handling, reduced interference between filters operating at different frequency bands, increased quality factor, and decreased form factor.

In some examples, increasing the width of the raised frame regions in a BAW resonator may increase the quality factor of the resonator and improve (reduce) the insertion loss of a filter including the BAW resonator. Increasing the width of the raised frame regions in a BAW resonator may, however, result in the generation of thickness extension vibration modes below the series resonance frequency of the resonator and increase gamma loading for other resonators or filters operating at lower frequencies, such as in devices utilizing carrier aggregation technologies.

Power handling of a BAW filter may be improved by utilizing resonator cascading, however, this will generally undesirably increase the area or die size of the BAW filter.

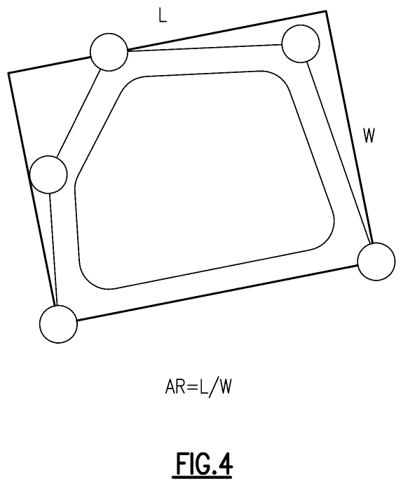

Aspects and embodiments disclosed herein utilize BAW resonators with high aspect ratios (AR) to increase the resonator quality factor Q at frequencies below the resonator series resonance frequency. As the term is used herein, given the smallest rectangle that can encompass the area of a resonator the aspect ratio of the resonator is equal to the length of the long side of the rectangle (L) divided by the length of the short side of the rectangle (W). See FIG. 4. It is to be understood that in FIG. 4 the long and short sides of the rectangle are not necessarily shown to scale relative to one another and may represent rectangles (or resonators) with any aspect ratio. Embodiments of resonators disclosed herein may have an aspect ratio of up to 6:1.

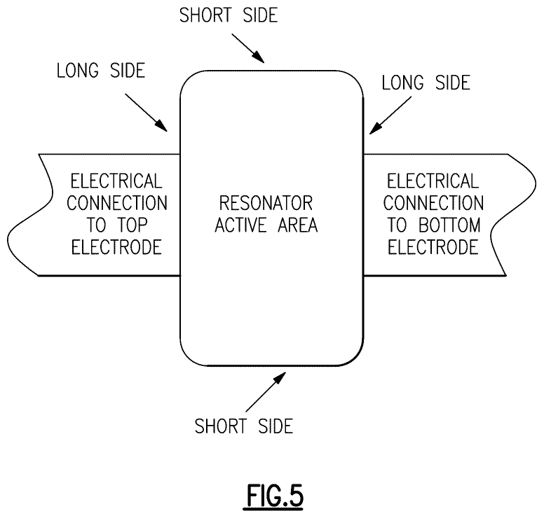

For band pass ladder filters, providing the series resonators with high ARs will also improve the low and middle channel insertion loss. If the electrical connections to the top and bottom electrodes of the BAW resonator are made on the longer sides of the resonator, for example, as schematically illustrated in FIG. 5, this may improve heat dissipation from the center of the resonator to its perimeter, thus enhancing the power handling of the resonator.

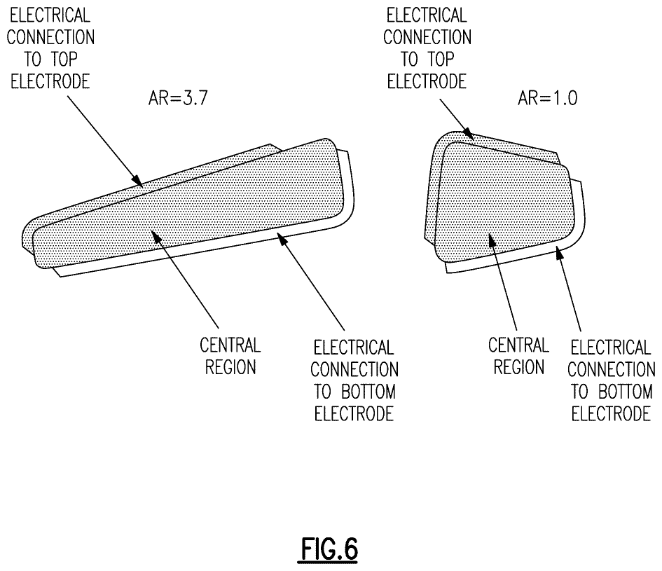

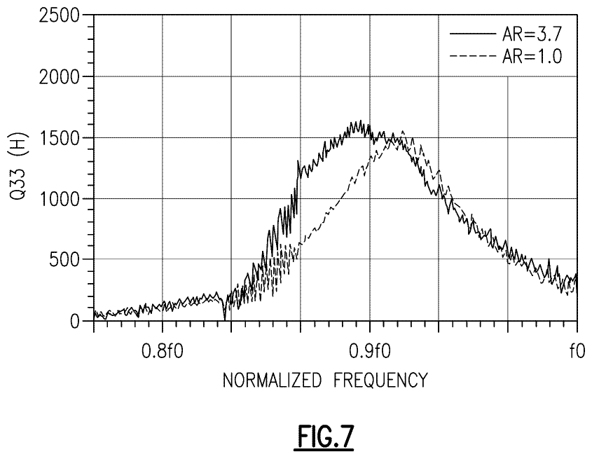

Examples of shapes of BAW resonators with different aspect ratios (AR=3.7 and AR=1.0) are illustrated in FIG. 6. FIG. 7 illustrates results of a simulation of the effect on resonator Q of increasing the resonator AR from 1.0 to 3.7. As can be observed, the quality factor for the resonator with the higher AR is significantly increased as compared to the resonator with the lower AR at frequencies below the series resonance frequency of the resonators.

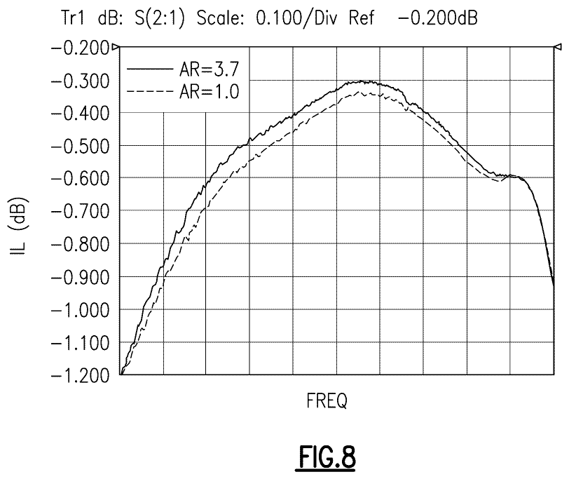

FIG. 8 is a chart comparing results of a simulation of insertion loss of acoustic wave filters formed from resonators having different ARs such as illustrated in FIG. 6. As can be observed from the different curves in FIG. 8, the filter formed from the resonators with the AR of 3.7 exhibits an improvement in insertion loss of as much as 0.1 dB for the passband as compared to the filter formed from the resonators with the AR of 1.0.

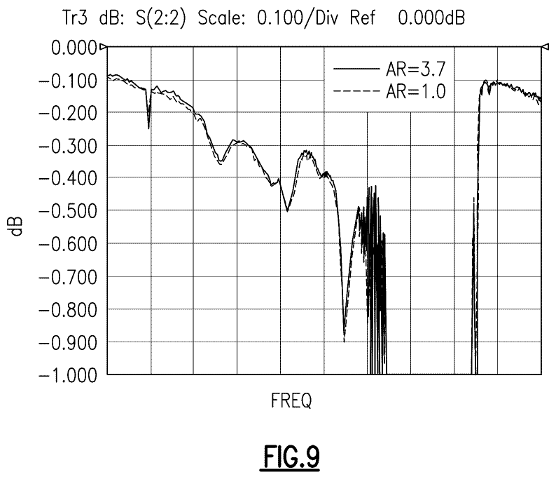

FIG. 9 is a chart comparing results of a simulation of out of band filter return loss at an antenna port for ladder filters including antenna side first series arm bulk acoustic wave resonators having different ARs such as illustrated in FIG. 6. The out of band filter return loss for the filter including the series arm resonators with the AR of 3.7 is closer to zero than the out of band filter return loss for the filter including the series arm resonators with the AR of 1.0, which is preferable, as this indicates that the out of band signals will be reflected to a greater degree rather than passing through the filter in the out of band frequency range shown. As a result, due to the improved Q or conductance floor in the range below the series resonance frequency in the out of band carrier aggregation bands for the resonators with the greater AR, gamma loading is reduced, hence improving the insertion loss of other filters operating in the lower frequency bands in the same device. For example, if a filter operating in the B41 band was utilized together in a carrier aggregation (CA) configuration with filters operating in the lower frequency B32, B3Rx, B1Rx, and/or B40 bands were built with high AR resonators as opposed to lower AR resonators, improved return loss of high AR resonator will reduce the Gamma loading into other CA band filters, hence improving the CA filter insertion loss.

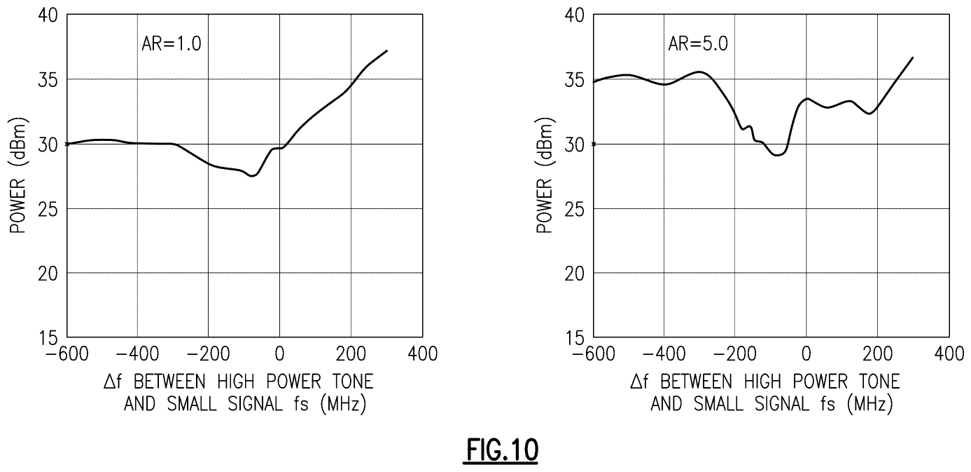

As noted above, increasing the AR of a BAW resonator may improve its power durability. Simulations were performed to assess the maximum power handling in ladder filters including series arm BAW resonators with ARs of either 1.0 or 5.0 and operating in the 5GHz band. The results of these simulations are shown in FIG. 10. As can be seen in the chart in FIG. 10, for the filter with the resonators having the AR of 5.0 as compared to the filter having the resonators with the AR of 1.0, the filter break down power increased for frequencies from 600 MHz below the series resonance frequency to 100 MHz above the series resonance frequency.

Aspects and embodiments of filters including high aspect ratio BAW resonators, either film bulk acoustic wave resonators or solidly mounted resonators, may be used in a wide variety of electronic devices. For example, the BAW filter can be used in an antenna duplexer or multiplexer implementing carrier aggregation functionality, which itself can be incorporated into a variety of electronic devices, such as RF front-end modules and communication devices.

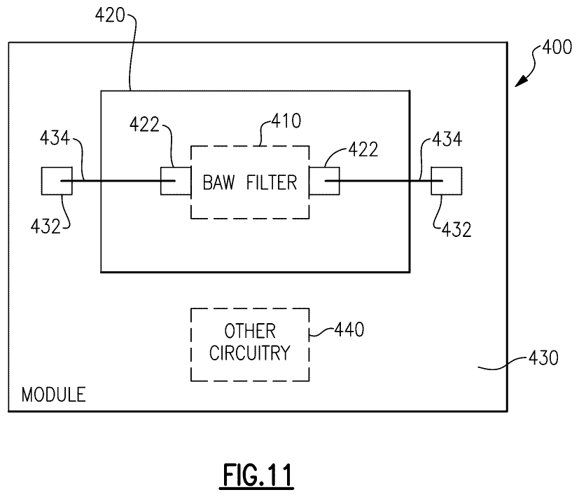

FIG. 11 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

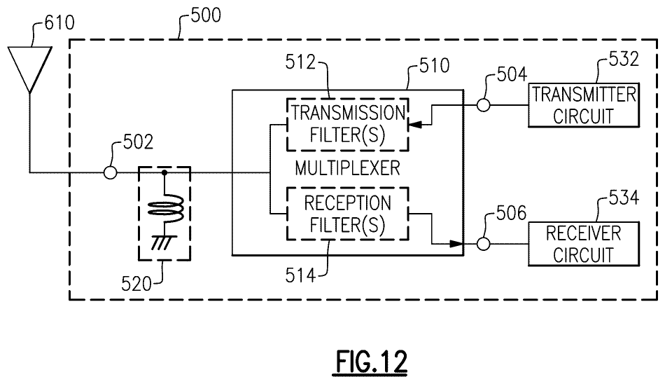

Referring to FIG. 12, there is illustrated a block diagram of one example of a front-end module 500, which may be used in an electronic device such as a wireless communications device (e.g., a mobile phone) for example. The front-end module 500 includes an antenna multiplexer 510 having a common node 502, an input node 504, and an output node 506. An antenna 610 is connected to the common node 502.

The antenna multiplexer 510 may implement carrier aggregation and may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the multiplexer 510 and a receiver circuit 534 connected to the output node 506 of the multiplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 12, however in other embodiments these components may be integrated into a common transceiver circuit or module. As will be appreciated by those skilled in the art, the front-end module 500 may include other components that are not illustrated in FIG. 12 including, but not limited to, switches, electromagnetic couplers, amplifiers, processors, and the like.

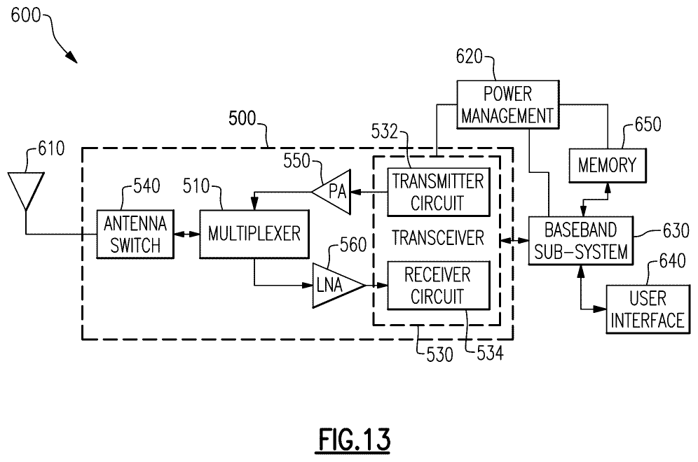

FIG. 13 is a block diagram of one example of a wireless device 600 including the antenna multiplexer 510 shown in FIG. 12. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 12. The front-end module 500 includes the multiplexer 510, as discussed above. In the example shown in FIG. 13 the front-end module 500 further includes an antenna switch 540, which can be configured to switch between different frequency bands or modes, such as transmit and receive modes, for example. In the example illustrated in FIG. 13, the antenna switch 540 is positioned between the multiplexer 510 and the antenna 610; however, in other examples the multiplexer 510 can be positioned between the antenna switch 540 and the antenna 610. In other examples the antenna switch 540 and the multiplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the multiplexer 510, and the receiver circuit 534, which can be connected to the output node 506 of the multiplexer 510, as shown in the example of FIG. 12.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 500 may further include a low noise amplifier module 560, which amplifies received signals from the antenna 610 and provides the amplified signals to the receiver circuit 534 of the transceiver 530.

The wireless device 600 of FIG. 13 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to. ” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A radio frequency filter comprising:
a plurality of series arm bulk acoustic wave resonators connected in series between an input and an output of the filter; and
a plurality of shunt bulk acoustic wave resonators connected between nodes between adjacent series arm bulk acoustic wave resonators and ground, at least one of the plurality of series arm bulk acoustic wave resonators having a greater aspect ratio than at least one of the plurality of shunt bulk acoustic wave resonators.

2. The filter of claim 1 wherein the at least one of the plurality of series arm bulk acoustic wave resonators has a greater aspect ratio than each of the plurality of shunt bulk acoustic wave resonators.

3. The filter of claim 2 wherein each of the plurality of series arm bulk acoustic wave resonators has a greater aspect ratio than any of the plurality of shunt bulk acoustic wave resonators.

4. The filter of claim 1 wherein one of the input or the output is an antenna port and the at least one of the plurality of series arm bulk acoustic wave resonators is a series arm bulk acoustic wave resonator closest to the antenna port.

5. The filter of claim 1 wherein the aspect ratio of the at least one of the plurality of series arm bulk acoustic wave resonators is at least 2:1.

6. The filter of claim 5 wherein the aspect ratio of the at least one of the plurality of series arm bulk acoustic wave resonators is at least 3:1.

7. The filter of claim 6 wherein the aspect ratio of the at least one of the plurality of series arm bulk acoustic wave resonators is 5:1 or more.

8. The filter of claim 1 wherein the at least one of the plurality of series arm bulk acoustic wave resonators includes a first side and a second side, the first side being longer than the second side, an electrical connection to a first electrode of the at least one of the plurality of series arm bulk acoustic wave resonators being disposed on the first side.

9. The filter of claim 8 wherein the at least one of the plurality of series arm bulk acoustic wave resonators includes a third side, the first side and the third side each being longer than all other sides of the at least one of the plurality of series arm bulk acoustic wave resonators, an electrical connection to a second electrode of the at least one of the plurality of series arm bulk acoustic wave resonators being disposed on the third side.

10. The filter of claim 1 wherein the plurality of series arm bulk acoustic wave resonators are film bulk acoustic wave resonators.

11. The filter of claim 1 wherein the plurality of series arm bulk acoustic wave resonators are solidly mounted resonators.

12. An electronic device module comprising a radio frequency filter including a plurality of series arm bulk acoustic wave resonators connected in series between an input and an output of the filter, and a plurality of shunt bulk acoustic wave resonators connected between nodes between adjacent series arm bulk acoustic wave resonators and ground, at least one of the plurality of series arm bulk acoustic wave resonators having a greater aspect ratio than at least one of the plurality of shunt bulk acoustic wave resonators.

13. The electronic device module of claim 12 wherein the at least one of the plurality of series arm bulk acoustic wave resonators has a greater aspect ratio than each of the plurality of shunt bulk acoustic wave resonators.

14. The electronic device module of claim 13 wherein each of the plurality of series arm bulk acoustic wave resonators has a greater aspect ratio than any of the plurality of shunt bulk acoustic wave resonators.

15. A multiplexer including a plurality of radio frequency filters, at least one of the plurality of radio frequency filters comprising:
a plurality of series arm bulk acoustic wave resonators connected in series between an input and an output of the filter; and
a plurality of shunt bulk acoustic wave resonators connected between nodes between adjacent series arm bulk acoustic wave resonators and ground, at least one of the plurality of series arm bulk acoustic wave resonators having a greater aspect ratio than at least one of the plurality of shunt bulk acoustic wave resonators.

16. The multiplexer of claim 15 wherein the at least one of the plurality of radio frequency filters has a higher operating frequency than at least one other of the plurality of radio frequency filters.

17. The multiplexer of claim 16 wherein the at least one of the plurality of radio frequency filters has a higher operating frequency than each other of the plurality of radio frequency filters.

18. The multiplexer of claim 15 wherein the at least one of the plurality of series arm bulk acoustic wave resonators has a greater aspect ratio than each of the plurality of shunt bulk acoustic wave resonators.

19. The multiplexer of claim 18 wherein each of the plurality of series arm bulk acoustic wave resonators has a greater aspect ratio than any of the plurality of shunt bulk acoustic wave resonators.

20. The multiplexer of claim 15 wherein one of the input or the output is an antenna port and the at least one of the plurality of series arm bulk acoustic wave resonators is a series arm bulk acoustic wave resonator closest to the antenna port.
